(19) United States
(12) Patent Application Publication
(10) Pub. No.: US 2024/0128366 A1
(43) Pub. Date: Apr. 18, 2024

(54) NITRIDE SEMICONDUCTOR DEVICE

(71) Applicant: ROHM CO., LTD., Kyoto (JP)

(72) Inventor: Shinya TAKADO, Kyoto (JP)

(73) Assignee: ROHM CO., LTD., Kyoto (JP)

(21) Appl. No.: 18/487,138

(22) Filed: Oct. 16, 2023

(30) Foreign Application Priority Data
Oct. 17, 2022 (JP) 2022-166305

(51) Int. Cl. H01L 29/778; H01L 29/20; H01L 29/43

(52) U.S. Cl. CPC H01L 29/7786; H01L 29/2003; H01L 29/432

(57) ABSTRACT

A nitride semiconductor device includes: a first nitride semiconductor layer made of a nitride semiconductor; a second nitride semiconductor layer made of a nitride semiconductor having a bandgap larger than that of the first nitride semiconductor layer; a gate electrode located above the second nitride semiconductor layer; and a source electrode and a drain electrode formed on the second nitride semiconductor layer, wherein the first nitride semiconductor layer includes one or more stacked bodies, each of which includes a doped layer as a carbon-doped gallium nitride layer, and a non-doped layer as a non-doped gallium nitride layer formed on the doped layer, and wherein in a region below at least one of the gate electrode or the drain electrode, the number of dislocation lines passing through a top surface of the non-doped layer is smaller than the number of dislocation lines passing through a bottom surface of the non-doped layer.

### CROSS-REFERENCE TO RELATED APPLICATION

This application is based upon and claims the benefit of priority from Japanese Patent Application No. 2022-166305, filed on Oct. 17, 2022, the entire contents of which are incorporated herein by reference.

### TECHNICAL FIELD

The present disclosure relates to a nitride semiconductor device.

### BACKGROUND

Currently, high electron mobility transistors (HEMTs) using nitride semiconductors such as gallium nitride (GaN) are being commercialized. For example, there is a known HEMT that includes a semiconductor substrate, a buffer layer formed on the semiconductor substrate, a GaN electron transit layer formed on the buffer layer, and an AlGaN electron supply layer formed on the GaN electron transit layer. The electron transit layer and the electron supply layer form a heterojunction, and thus a two-dimensional electron gas (2DEG) that functions as an HEMT channel is generated in the electron transit layer in a vicinity of an interface between the electron transit layer and the electron supply layer.

### BRIEF DESCRIPTION OF DRAWINGS

The accompanying drawings, which are incorporated in and constitute a part of the specification, illustrate embodiments of the present disclosure.

FIG. 1 is a schematic cross-sectional view of an exemplary nitride semiconductor device according to an embodiment.

FIG. 2 is a schematic diagram showing dislocation lines in a first nitride semiconductor layer.

FIG. 3 is a schematic diagram showing bending of the dislocation lines at an interface between a doped layer and a non-doped layer.

FIG. 4 is a schematic cross-sectional view of an exemplary nitride semiconductor device according to a first modification.

FIG. 5 is a schematic cross-sectional view of an exemplary nitride semiconductor device according to a second modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments of a nitride semiconductor device of the present disclosure will now be described with reference to the accompanying drawings. It should be noted that, for simplicity and clarity of explanation, components shown in the drawings are not necessarily drawn to scale. In order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### (Cross-Sectional Structure of Nitride Semiconductor Device)

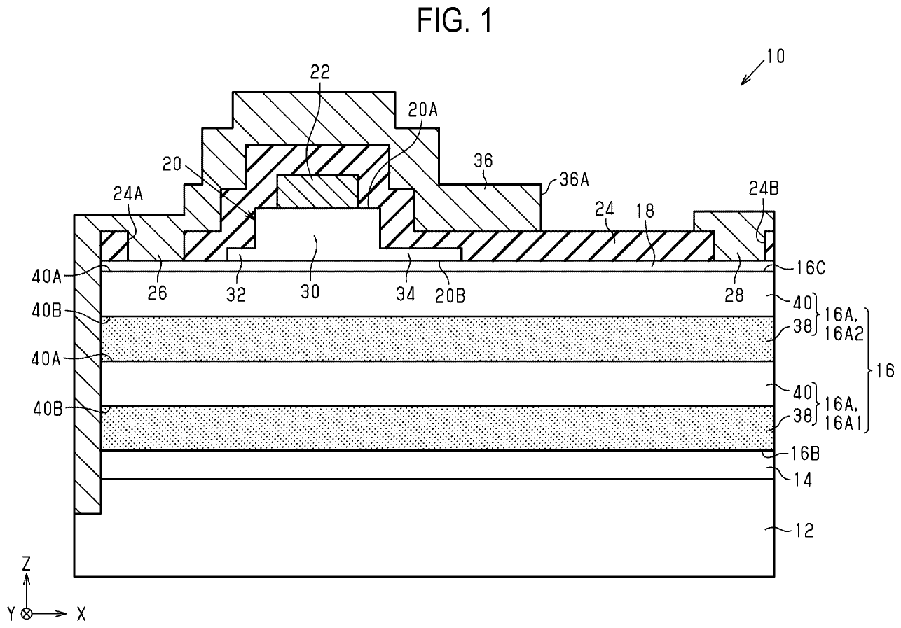

FIG. 1 is a schematic cross-sectional view of an exemplary nitride semiconductor device 10 according to an embodiment. A nitride semiconductor device 10 may include a semiconductor substrate 12 and a buffer layer 14 formed on the semiconductor substrate 12. A Z-axis direction of mutually orthogonal XYZ axes shown in FIG. 1 is a direction orthogonal to a surface of the semiconductor substrate 12. The term “in a plan view” used in the present disclosure refers to viewing the nitride semiconductor device 10 from above along the Z-axis direction unless explicitly stated otherwise. The nitride semiconductor device 10 further includes a first nitride semiconductor layer 16 formed on the buffer layer 14 and a second nitride semiconductor layer 18 formed on the first nitride semiconductor layer 16.

The semiconductor substrate 12 may be formed from silicon (Si), silicon carbide (SiC), gallium nitride (GaN), sapphire, or other substrate materials. In one example, the semiconductor substrate 12 may be a Si substrate. A thickness of the semiconductor substrate 12 may be, for example, 200 μm or more and 1,500 μm or less.

The buffer layer 14 may include one or more nitride semiconductor layers. The buffer layer 14 may be made of any material capable of suppressing occurrence of warping of the semiconductor substrate 12 and cracks in the nitride semiconductor device 10, which may be caused by, for example, a mismatch in thermal expansion coefficients between the semiconductor substrate 12 and the first nitride semiconductor layer 16. For example, the buffer layer 14 may include at least one of an aluminum nitride (AlN) layer, an aluminum gallium nitride (AlGaN) layer, or a graded AlGaN layer having different aluminum (Al) compositions. For example, the buffer layer 14 may be formed by a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 may include a first buffer layer which is an AlN layer formed on the semiconductor substrate 12, and a second buffer layer which is an AlGaN layer formed on the AlN layer. The first buffer layer may be, for example, an AlN layer having a thickness of 100 nm to 300 nm, while the second buffer layer may be formed, for example, by stacking a graded AlGaN layer having a thickness of 100 nm to 300 nm multiple times. In addition, in order to suppress a leakage current in the buffer layer 14, impurities may be introduced into a part of the buffer layer 14 to make the buffer layer 14 semi-insulating. In that case, the impurities are, for example, carbon (C) or iron (Fe), and a concentration of the impurities may be, for example, 4×10¹⁶ cm⁻³ or more.

The first nitride semiconductor layer 16 is made of a nitride semiconductor. The first nitride semiconductor layer 16 may be, for example, a GaN layer. A thickness of the first nitride semiconductor layer 16 may be, for example, 0.5 μm or more and 2 μm or less. The first nitride semiconductor layer 16 includes one or more stacked bodies 16A. In the example of FIG. 1, the first nitride semiconductor layer 16 includes two stacked bodies 16A, but the number of stacked bodies 16A included in the first nitride semiconductor layer 16 is not limited to this example. In one example, the number of stacked bodies 16A included in the first nitride semiconductor layer 16 may be one, two, or three. Further details of the stacked bodies 16A will be described later.

The second nitride semiconductor layer 18 is composed of a nitride semiconductor having a bandgap larger than that of the first nitride semiconductor layer 16. The second nitride semiconductor layer 18 may be, for example, an AlGaN layer. Since a bandgap increases as an Al composition increases, the second nitride semiconductor layer 18, which is the AlGaN layer, has a larger bandgap than the first nitride semiconductor layer 16 which is the GaN layer. In one example, the second nitride semiconductor layer 18 is made of AlₓGa₁₋ₓN, where x is 0.1<x<0.4, more specifically 0.1<x<0.3. The second nitride semiconductor layer 18 may have a thickness of 5 nm or more and 20 nm or less. In one example, the second nitride semiconductor layer 18 may have a thickness of 8 nm or more.

The first nitride semiconductor layer 16 and the second nitride semiconductor layer 18 are made of nitride semiconductors having different lattice constants. Therefore, the nitride semiconductor (for example, GaN) constituting the first nitride semiconductor layer 16 and the nitride semiconductor (for example, AlGaN) constituting the second nitride semiconductor layer 18 form a lattice-mismatched heterojunction. Due to spontaneous polarization of the first nitride semiconductor layer 16 and the second nitride semiconductor layer 18 and piezoelectric polarization caused by crystal strain in a vicinity of a heterojunction interface, an energy level of a conduction band of the first nitride semiconductor layer 16 in the vicinity of the heterojunction interface is lower than the Fermi level. As a result, a two-dimensional electron gas (2DEG) spreads in the first nitride semiconductor layer 16 at a location near the heterojunction interface between the first nitride semiconductor layer 16 and the second nitride semiconductor layer 18 (for example, within a range of several nanometers from the interface). Since the 2DEG in the first nitride semiconductor layer 16 functions as a channel of the nitride semiconductor device 10, at least a part of the first nitride semiconductor layer 16 is also referred to as an electron transit layer. In addition, the second nitride semiconductor layer 18 is also referred to as an electron supply layer. In one example, by increasing at least one of the Al composition or the thickness of the second nitride semiconductor layer 18, a sheet carrier density of the 2DEG generated in the first nitride semiconductor layer 16 can be increased.

### (Gate Layer and Gate Electrode)

The nitride semiconductor device 10 may further include a gate layer 20 formed on the second nitride semiconductor layer 18 and a gate electrode 22 formed on the gate layer 20. The gate layer 20 may be formed on a part of the second nitride semiconductor layer 18. The gate electrode 22 is located above the second nitride semiconductor layer 18.

The gate layer 20 is made of a nitride semiconductor containing acceptor-type impurities. In the present embodiment, the gate layer 20 may be a gallium nitride layer doped with acceptor-type impurities (i.e., a p-type GaN layer). The acceptor-type impurities may include at least one of zinc (Zn), magnesium (Mg), or carbon (C). A maximum concentration of the acceptor-type impurities in the gate layer 20 may be set to 7×10¹⁸ cm⁻³ or more and 1×10²⁰ cm⁻³ or less. In one example, the gate layer 20 may be a GaN layer containing at least one of Mg or Zn as impurities. A cross-sectional shape of the gate layer 20 will be described later.

The gate electrode 22 may be composed of one or more metal layers. In one example, the gate electrode 22 may be composed of a titanium nitride (TiN) layer. In another example, the gate electrode 22 may be composed of a first metal layer made of titanium (Ti), and a second metal layer made of TiN and provided on the first metal layer. The gate electrode 22 may form a Schottky junction with the gate layer 20. The gate electrode 22 may be formed in a region smaller than the gate layer 20 in a plan view. A thickness of the gate electrode 22 may be, for example, 50 nm or more and 200 nm or less.

The nitride semiconductor device 10 may further include a passivation layer 24 that covers the second nitride semiconductor layer 18, the gate layer 20, and the gate electrode 22. The passivation layer 24 has a first opening 24A and a second opening 24B that expose a surface of the second nitride semiconductor layer 18. In the illustrated example, the first opening 24A and the second opening 24B may be spaced apart from each other in the X-axis direction. The gate layer 20 is located between the first opening 24A and the second opening 24B. More specifically, the gate layer 20 may be interposed between the first opening 24A and the second opening 24B, and may be located closer to the first opening 24A than the second opening 24B. The passivation layer 24 may be formed of, for example, at least one of silicon nitride (SiN), silicon dioxide (SiO₂), silicon oxynitride (SiON), aluminum oxide (Al₂O₃), AN, or aluminum oxynitride (AlON). A thickness of the passivation layer 24 may be, for example, 80 nm or more and 150 nm or less.

### (Source Electrode and Drain Electrode)

The nitride semiconductor device 10 further includes a source electrode 26 which is in contact with the second nitride semiconductor layer 18 via the first opening 24A, and a drain electrode 28 which is in contact with the second nitride semiconductor layer 18 via the second opening 24B. The source electrode 26 and the drain electrode 28 may be composed of one or more metal layers (for example, any combination of Ti, TiN, Al, AlSiCu, and AlCu layers).

Since at least a part of the source electrode 26 is filled in the first opening 24A, the source electrode 26 can make an ohmic contact with the 2DEG directly below the second nitride semiconductor layer 18 via the first opening 24A. Similarly, since at least a part of the drain electrode 28 is filled in the second opening 24B, the drain electrode 28 can make an ohmic contact with the 2DEG directly below the second nitride semiconductor layer 18 via the second opening 24B.

The source electrode 26 and the drain electrode 28 may be configured so that a source voltage and a drain voltage are applied respectively thereto. The semiconductor substrate 12 may be configured to be electrically connected to the source electrode 26 so that the source voltage is applied thereto. Therefore, the semiconductor substrate 12 may have the same potential as the source electrode 26. On the other hand, the semiconductor substrate 12 may have a different potential from the gate electrode 22 and the drain electrode 28.

### (Cross-sectional Shape of Gate Layer)

The gate layer 20 may include a top surface 20A on which the gate electrode 22 is formed, and a bottom surface 20B in contact with the second nitride semiconductor layer 18. In the example shown in FIG. 1, the gate layer 20 may include a ridge portion 30 that includes the top surface 20A, and a source-side extension portion 32 and a drain-side extension portion 34 which are thinner than the ridge portion 30. The ridge portion 30, the source-side extension portion 32, and the drain-side extension portion 34 are all in contact with the second nitride semiconductor layer 18. The source-side extension portion 32 and the drain-side extension portion 34 extend outward from the ridge portion 30 in a plan view. In addition, in the present disclosure, each of the source-side extension portion 32 and the drain-side extension portion 34 is also simply referred to as an “extension portion.”

The source-side extension portion 32 extends from the ridge portion 30 toward the first opening 24A. The passivation layer 24 is interposed between the source electrode 26 embedded in the first opening 24A and the source-side extension portion 32.

The drain-side extension portion 34 extends from the ridge portion 30 toward the second opening 24B. The passivation layer 24 is interposed between the drain electrode 28 embedded in the second opening 24B and the drain-side extension portion 34.

The ridge portion 30 is located between the source-side extension portion 32 and the drain-side extension portion 34, and is formed integrally with the source-side extension portion 32 and the drain-side extension portion 34. Due to the presence of the source-side extension portion 32 and the drain-side extension portion 34, the bottom surface 20B of the gate layer 20 has a larger area than the top surface 20A. In the example shown in FIG. 1, the drain-side extension portion 34 may extend longer toward the outside of the ridge portion 30 than the source-side extension portion 32 in a plan view. That is, the drain-side extension portion 34 may have a larger dimension in the X-axis direction than the source-side extension portion 32. The source-side extension portion 32 may have a dimension of, for example, 0.2 μm or more and 0.3 μm or less in the X-axis direction. On the other hand, the drain-side extension portion 34 may have a dimension of, for example, 0.2 μm or more and 0.6 μm or less in the X-axis direction.

The ridge portion 30 corresponds to a relatively thick portion of the gate layer 20. The ridge portion 30 may have a thickness of, for example, 80 nm or more and 150 nm or less. The thickness of the ridge portion 30 may be determined in consideration of parameters including a gate threshold voltage. In one example, the ridge portion 30 may have a thickness greater than 110 nm.

Each of the source-side extension portion 32 and the drain-side extension portion 34 has a thickness smaller than the thickness of the ridge portion 30. In one example, each of the source-side extension portion 32 and the drain-side extension portion 34 may have a thickness that is equal to or less than half the thickness of the ridge portion 30.

Each of the source-side extension portion 32 and the drain-side extension portion 34 may include a flat portion having a substantially constant thickness. In one example, the flat portions of the source-side extension portion 32 and the drain-side extension portion 34 may have a thickness of 5 nm or more and 25 nm or less. In addition, in the present disclosure, “substantially constant thickness” refers to a thickness within a range of manufacturing variations (for example, 20%). Although not shown, each of the source-side extension portion 32 and the drain-side extension portion 34 may further include an intermediate portion, which is thicker than the flat portion and is located between the flat portion and the ridge portion 30. In one example, the intermediate portion may have a thickness that tapers away from the ridge portion 30.

### (Field Plate Electrode)

The nitride semiconductor device 10 may optionally further include a field plate electrode 36, which is formed on the passivation layer 24 and extends at least partially into a region between the gate layer 20 and the drain electrode 28 in a plan view. In the example shown in FIG. 1, the field plate electrode 36 is formed integrally with the source electrode 26. Among the integrally formed electrodes, the source electrode 26 may include at least a portion buried in the first opening 24A of the passivation layer 24, and the field plate electrode 36 may include the remaining portion that covers the passivation layer 24.

The field plate electrode 36 is spaced apart from the drain electrode 28. The field plate electrode 36 may include an end portion 36A located between the drain electrode 28 (the second opening 24B) and the gate layer 20 (the drain-side extension portion 34) in a plan view.

The field plate electrode 36 can alleviate electric field concentration in a vicinity of the end portion of the gate electrode 22, when a drain voltage is applied to the drain electrode 28 in a zero bias state where no gate voltage is applied to the gate electrode 22.

### (Stacked Body of First Nitride Semiconductor Layer)

As described above, the first nitride semiconductor layer 16 includes one or more stacked bodies 16A. Each stacked body 16A includes a doped layer 38 which is a GaN layer doped with carbon, and a non-doped layer 40 which is a non-doped GaN layer and is formed on the doped layer 38. Each stacked body 16A is composed of a pair of doped layer 38 and non-doped layer 40. In addition, the term “non-doped layer” used in the present disclosure is defined as a layer in which impurities are intentionally not introduced. A carbon concentration in the doped layer 38 may be between 5×10¹⁷ cm⁻³ and 5×10¹⁹ cm⁻³.

In each stacked body 16A, the doped layer 38 may have the same thickness as the non-doped layer 40, or may have a different thickness from the non-doped layer 40. In addition, each stacked body 16A may have the same thickness as another stacked body 16A, or may have a different thickness from another stacked body 16A.

The first nitride semiconductor layer 16 has a structure in which the doped layers 38 and the non-doped layers 40 are alternately stacked. In the example of FIG. 1, the first nitride semiconductor layer 16 includes two stacked bodies 16A. Here, between the two stacked bodies 16A, the lower one is referred to as a first stacked body 16A1, and the upper one is referred to as a second stacked body 16A2. The first stacked body 16A1 includes a bottom surface 16B of the first nitride semiconductor layer 16. The second stacked body 16A2 includes a top surface 16C of the first nitride semiconductor layer 16. The first stacked body 16A1 is formed on the buffer layer 14. The second stacked body 16A2 is formed on the first stacked body 16A1. The second nitride semiconductor layer 18 is formed on the second stacked body 16A2.

As shown in FIG. 1, the non-doped layer 40 has a bottom surface 40B in contact with the doped layer 38 and a top surface 40A opposite to the bottom surface 40B. The top surface 40A of the non-doped layer 40 of each stacked body 16A may be in contact with the doped layer 38 of another stacked body 16A or the second nitride semiconductor layer 18. In the example of FIG. 1, the top surface 40A of the non-doped layer 40 of the first stacked body 16A1 is in contact with the doped layer 38 of the second stacked body 16A2, while the top surface 40A of the non-doped layer 40 of the second stacked body 16A2 is in contact with the second nitride semiconductor layer 18.

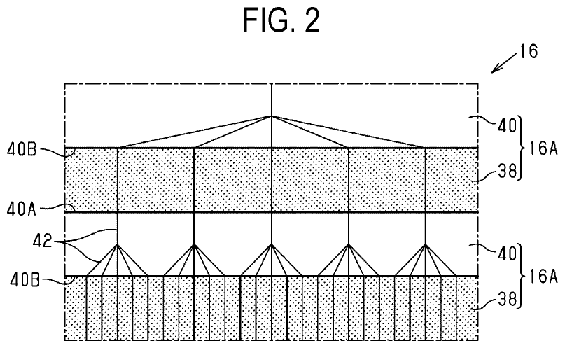

FIG. 2 is a schematic diagram showing dislocation lines 42 in the first nitride semiconductor layer 16. FIG. 2 shows a part of a cross section of the plurality of stacked bodies 16A. Dislocation having the dislocation lines 42 is a type of linear lattice defect in the first nitride semiconductor layer 16. The dislocation lines 42 can be visually recognized by observing a cross section of the nitride semiconductor device 10 using transmission electron microscopy (TEM).

Each stacked body 16A (the doped layer 38 and the non-doped layer 40) includes the plurality of dislocation lines 42. At least some of the plurality of dislocation lines 42 may be bent inside the stacked body 16A. At least some of the plurality of dislocation lines 42 may extend continuously through both the doped layer 38 and the non-doped layer 40. In addition, in FIG. 2, all the dislocation lines 42 in the stacked bodies 16A are depicted as being bent for the sake of explanation, but the present disclosure is not limited thereto.

As shown in FIG. 2, the number of dislocation lines 42 passing through the top surface 40A of the non-doped layer 40 is smaller than the number of dislocation lines 42 passing through the bottom surface 40B thereof. This is because at least some of the plurality of dislocation lines 42 are bent at an interface between the doped layer 38 and the non-doped layer 40 of each stacked body 16A. Since some of the dislocation lines 42 bent at the interface (the bottom surface 40B of the non-doped layer 40) are coupled to one another in the non-doped layer 40, the number of dislocation lines 42 passing through the top surface 40A of the non-doped layer 40 is smaller than the number of dislocation lines 42 passing through the bottom surface 40B thereof. In the present embodiment, in a region below at least one of the gate electrode 22 or the drain electrode 28, the number of dislocation lines 42 passing through the top surface 40A of the non-doped layer 40 is smaller than the number of dislocation lines 42 passing through the bottom surface 40B thereof. In one example, the number of dislocation lines 42 passing through the top surface 40A and the number of dislocation lines 42 passing through the bottom surface 40B may be compared using values counted in a plurality of cross sections at different locations in the nitride semiconductor device 10.

A dislocation density of the non-doped layer 40 may be lower than a dislocation density of the doped layer 38. In addition, a dislocation density of the non-doped layer 40 of the second stacked body 16A2 may be lower than a dislocation density of the non-doped layer 40 of the first stacked body 16A1.

### (Operations of Nitride Semiconductor Device)

Hereinafter, operations of the nitride semiconductor device 10 according to the present embodiment will be described. When a voltage exceeding the gate threshold voltage is applied to the gate electrode 22 of the nitride semiconductor device 10, the channel by the 2DEG is formed in the first nitride semiconductor layer 16 to make a source-drain electrical connection. When the first nitride semiconductor layer 16 includes the plurality of stacked bodies 16A, the 2DEG can be generated in the non-doped layer 40 of the stacked body 16A in contact with the second nitride semiconductor layer 18 (i.e., the second stacked body 16A2 in the example of FIG. 1).

On the other hand, during a zero bias, the 2DEG is not formed in at least a part of a region located below the gate layer 20 in the first nitride semiconductor layer 16. This is because the gate layer 20 contains the acceptor-type impurities, energy levels of the first nitride semiconductor layer 16 and the second nitride semiconductor layer 18 increase, thereby resulting in depletion of the 2DEG. A normally-off operation of the nitride semiconductor device 10 is implemented as described above.

The first nitride semiconductor layer 16 includes one or more stacked bodies 16A. Each stacked body 16A includes the doped layer 38 which is a carbon-doped gallium nitride layer, and the non-doped layer 40 which is a non-doped gallium nitride layer formed on the doped layer 38.

The first nitride semiconductor layer 16 (the doped layer 38 and the non-doped layer 40) contains dislocations (the dislocation lines 42) which are a type of linear lattice defects. The dislocations in the first nitride semiconductor layer 16 may be threading dislocations that are continuous with the dislocations in the buffer layer 14 below the first nitride semiconductor layer 16. For example, when the semiconductor substrate 12 is electrically connected to the source electrode 26, a potential difference is generated between an electrode (the gate electrode 22 or the drain electrode 28), which is disposed above the second nitride semiconductor layer 18, and the semiconductor substrate 12. For example, when the dislocations in the first nitride semiconductor layer 16 become threading dislocations that are continuous with the dislocations in the second nitride semiconductor layer 18 and the gate layer 20 formed above the first nitride semiconductor layer 16, a leakage current using these threading dislocations as a path may be generated.

However, with the nitride semiconductor device 10 according to the present embodiment, in the region below at least one of the gate electrode 22 or the drain electrode 28, the number of dislocation lines 42 passing through the top surface 40A of the non-doped layer 40 is smaller than the number of dislocation lines 42 passing through the bottom surface 40B thereof. As a result, conduction of a leakage current between the bottom surface 40B and the top surface 40A of the non-doped layer 40 can be suppressed, so that the leakage current of the nitride semiconductor device 10 can be reduced.

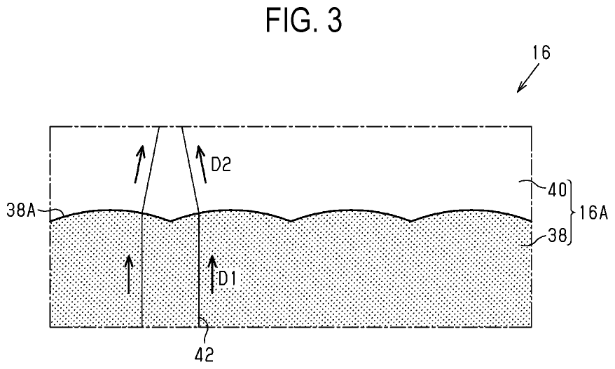

FIG. 3 is a schematic diagram showing bending of the dislocation lines 42 at the interface between the doped layer 38 and the non-doped layer 40. FIG. 3 shows a schematic enlarged view of the interface between the doped layer 38 and the non-doped layer 40. The doped layer 38 doped with carbon can be obtained by controlling a growth temperature and a growth rate of the GaN layer. For example, a surface (the top surface 38A) of the doped layer 38 obtained by relatively lowering the growth temperature of the GaN layer and increasing the growth rate thereof has unevenness. By such unevenness, a growth direction of the non-doped layer 40 formed on the top surface 38A of the doped layer 38 may change from a growth direction of the doped layer 38 (for example, a direction perpendicular to the semiconductor substrate 12). Therefore, a propagation direction of the dislocation lines 42 may also change at the interface between the doped layer 38 and the non-doped layer 40. In the illustrated example, the dislocation lines 42 extend in a direction D1 (for example, the direction perpendicular to the semiconductor substrate 12) in the doped layer 38, but extend in a direction D2 (for example, a direction perpendicular to the top surface 38A) in the non-doped layer 40, which is different from the direction D1. For example, when two dislocation lines 42 extending substantially parallel with each other exist in the doped layer 38, the two dislocation lines 42 extend in different directions in the non-doped layer 40, and as a result, the doped layer 38 and the non-doped layer 40 can be coupled to each other above the interface. Therefore, the number of dislocation lines 42 can be reduced at a position near a top in the stacked body 16A. As described above, the nitride semiconductor device 10 according to the present embodiment can use the bending of the dislocation lines 42 at the interface between the doped layer 38 and the non-doped layer 40 to reduce a leakage current flowing through the dislocation lines 42.

The nitride semiconductor device 10 according to the present embodiment has the following advantages.

(1) The first nitride semiconductor layer 16 includes one or more stacked bodies 16A. Each stacked body 16A includes the doped layer 38 which is a carbon-doped gallium nitride layer, and the non-doped layer 40 which is a non-doped gallium nitride layer formed on the doped layer 38. The non-doped layer 40 includes the plurality of dislocation lines 42, and has the bottom surface 40B in contact with the doped layer 38 and the top surface 40A opposite to the bottom surface 40B. In the region below at least one of the gate electrode 22 or the drain electrode 28, the number of dislocation lines 42 passing through the top surface 40A of the non-doped layer 40 is smaller than the number of dislocation lines 42 passing through the bottom surface 40B thereof. As a result, the leakage current of the nitride semiconductor device 10 can be reduced.

(2) The dislocation density of the non-doped layer 40 may be lower than the dislocation density of the doped layer 38. As a result, a leakage current path in the non-doped layer 40 in the stacked body 16A can be reduced.

(3) Each stacked body 16A includes the plurality of dislocation lines 42. At least some of the plurality of dislocation lines 42 may be bent inside the stacked body 16A. As a result, the dislocation lines 42 can be coupled to one another in the first nitride semiconductor layer 16.

(4) One or more stacked bodies 16A may include the first stacked body 16A1 and the second stacked body 16A2 formed on the first stacked body 16A1. As a result, the number of interfaces where the dislocation lines 42 are bent can be increased in the first nitride semiconductor layer 16, so that the leakage current path can be reduced.

(5) The dislocation density of the non-doped layer 40 of the second stacked body 16A2 may be lower than the dislocation density of the non-doped layer 40 of the first stacked body 16A1. As a result, the dislocation density of the first nitride semiconductor layer 16 can be made lower at a location closer to the second nitride semiconductor layer 18, so that a leakage current flowing in the thickness direction of the first nitride semiconductor layer 16 can be reduced.

(6) The nitride semiconductor device 10 may further include the gate layer 20, which is formed on the second nitride semiconductor layer 18 and made of a nitride semiconductor containing acceptor-type impurities. Thus, a normally-off operation of the nitride semiconductor device 10 can be implemented.

### [First Modification]

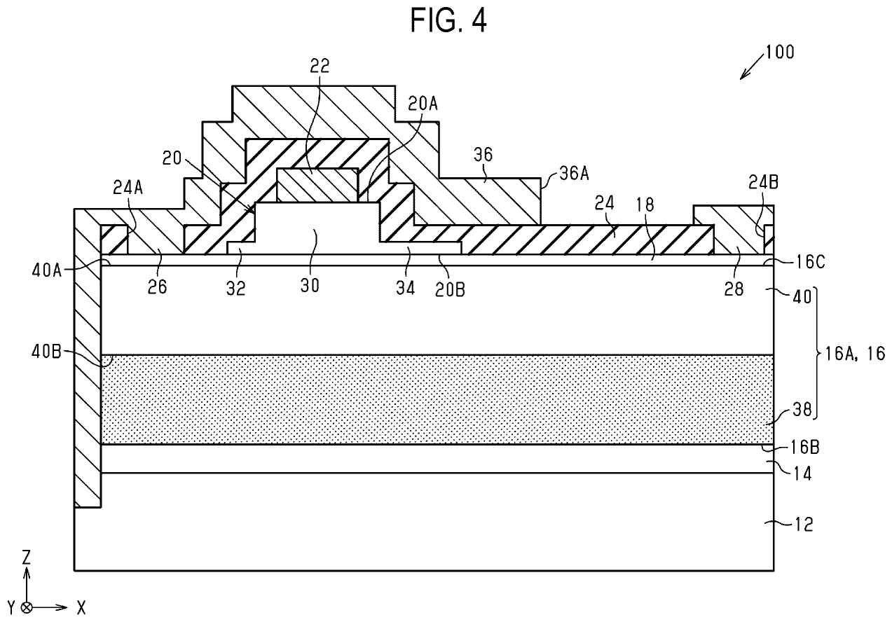

FIG. 4 is a schematic cross-sectional view of an exemplary nitride semiconductor device 100 according to a first modification. FIG. 4 shows an example in which the number of stacked bodies 16A included in the first nitride semiconductor layer 16 is one. The nitride semiconductor device 100 may be the same as the nitride semiconductor device 10 shown in FIG. 1 except that the number of stacked bodies 16A included in the first nitride semiconductor layer 16 is one. In FIG. 4, the same components as those of the nitride semiconductor device 10 shown in FIG. 1 are denoted by the same reference numerals. Further, detailed explanation of the same components as those of the nitride semiconductor device 10 will be omitted.

As shown in FIG. 4, the first nitride semiconductor layer 16 of the nitride semiconductor device 100 may include only one stacked body 16A. That is, in the example of FIG. 4, the first nitride semiconductor layer 16 may include the doped layer 38 and the non-doped layer 40 formed on the doped layer 38. In this case, the top surface 40A of the non-doped layer 40 corresponds to the top surface 16C of the first nitride semiconductor layer 16.

Also in the example of FIG. 4, in the region below at least one of the gate electrode 22 or the drain electrode 28, the number of dislocation lines 42 passing through the top surface 40A of the non-doped layer 40 is smaller than the number of dislocation lines 42 passing through the bottom surface 40B thereof. As a result, conduction of a current between the bottom surface 40B and the top surface 40A of the non-doped layer 40 can be suppressed. Therefore, a leakage current of the nitride semiconductor device 100 can be reduced.

### [Second Modification]

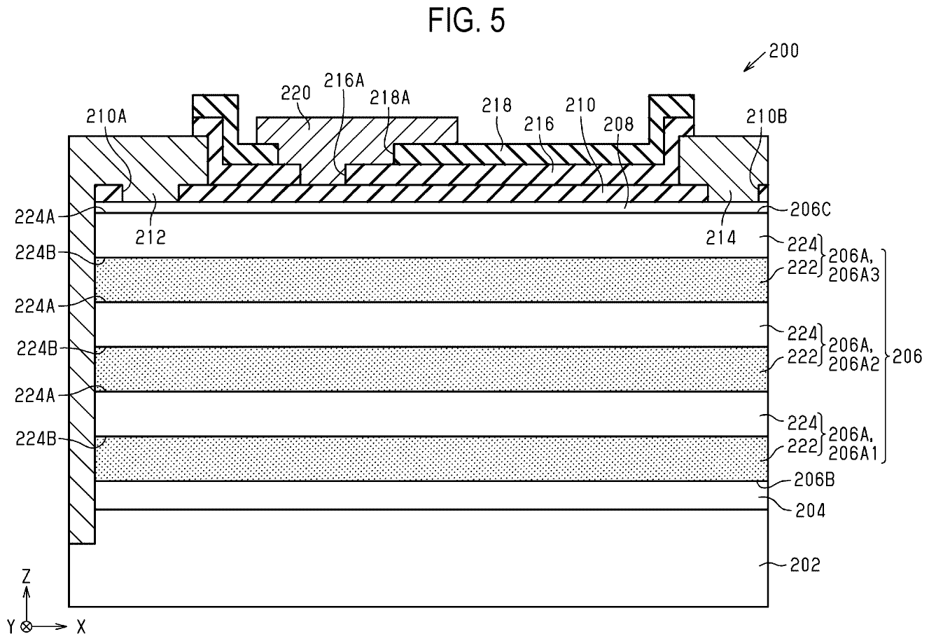

FIG. 5 is a schematic cross-sectional view of an exemplary nitride semiconductor device 200 according to a second modification. FIG. 5 shows an example in which the number of stacked bodies 16A included in the first nitride semiconductor layer 16 is three. In addition, the nitride semiconductor device 200 shown in FIG. 5 may be a depletion-type transistor that operates normally-on.

The nitride semiconductor device 200 may include a semiconductor substrate 202 and a buffer layer 204 formed on the semiconductor substrate 202. The semiconductor substrate 202 may be formed of silicon (Si), aluminum nitride (AlN), aluminum oxide (Al₂O₃), or other substrate materials. The semiconductor substrate 202 may be a QST (Qromis' Substrate Technology) substrate that contains amorphous AlN and Si formed on a surface of the amorphous AlN. A thickness of the semiconductor substrate 202 may be, for example, 200 μm or more and 1,500 μm or less.

The buffer layer 204 may include one or more nitride semiconductor layers. The buffer layer 204 may include, for example, at least one of an aluminum gallium nitride (AlGaN) layer, an AlN layer, or a graded AlGaN layer having different aluminum compositions.

The nitride semiconductor device 200 further includes a first nitride semiconductor layer 206 formed on the buffer layer 204, and a second nitride semiconductor layer 208 formed on the first nitride semiconductor layer 206. The first nitride semiconductor layer 206 is made of a nitride semiconductor. The first nitride semiconductor layer 206 may be, for example, a GaN layer. A thickness of the first nitride semiconductor layer 206 may be, for example, 0.5 μm or more and 2 μm or less. The first nitride semiconductor layer 206 includes one or more stacked bodies 206A. In the example of FIG. 5, the first nitride semiconductor layer 206 includes three stacked bodies 206A, but the number of stacked bodies 206A included in the first nitride semiconductor layer 206 is not limited to this example. In one example, the number of stacked bodies 206A included in the first nitride semiconductor layer 206 may be one, two, or three. Further details of the stacked bodies 206A will be described later.

The second nitride semiconductor layer 208 is made of a nitride semiconductor having a larger bandgap than the first nitride semiconductor layer 206. The second nitride semiconductor layer 208 may be, for example, an AlGaN layer. Since a bandgap increases as an Al composition increases, the second nitride semiconductor layer 208, which is the AlGaN layer, has a larger bandgap than the first nitride semiconductor layer 206, which is the GaN layer. In one example, the second nitride semiconductor layer 208 is made of AlₓGa₁₋ₓN, where x is 0.1<x<0.4, more specifically 0.1<x<0.3. The second nitride semiconductor layer 208 may have a thickness of 20 nm or more and 30 nm or less.

The first nitride semiconductor layer 206 and the second nitride semiconductor layer 208 are made of nitride semiconductors having different lattice constants. Therefore, a two-dimensional electron gas (2DEG) spreads in the first nitride semiconductor layer 206 at a location near a heterojunction interface between the first nitride semiconductor layer 206 and the second nitride semiconductor layer 208 (for example, within a range of several nanometers from the interface).

The nitride semiconductor device 200 further includes a gate insulating layer 210, a source electrode 212, and a drain electrode 214, which are formed on the second nitride semiconductor layer 208. The gate insulating layer 210 may be made of any material that can insulate the second nitride semiconductor layer 208 from a gate electrode 220 to be described later. For example, the gate insulating layer 210 may contain at least one of silicon nitride (SiN) or AlN. In one example, the gate insulating layer 210 may include a SiN layer and an AlN layer formed on the SiN layer.

The gate insulating layer 210 has a first opening 210A and a second opening 210B that expose a surface of the second nitride semiconductor layer 208. In the illustrated example, the first opening 210A and the second opening 210B may be spaced apart from each other in the X-axis direction. The source electrode 212 fills the first opening 210A and is in contact with the second nitride semiconductor layer 208 via the first opening 210A. The drain electrode 214 fills the second opening 210B and is in contact with the second nitride semiconductor layer 208 via the second opening 210B.

Each of the source electrode 212 and the drain electrode 214 may be composed of one or more metal layers (for example, any combination of Ti, TiN, Al, AlSiCu, and AlCu layers). In one example, each of the source electrode 212 and the drain electrode 214 may include a Ti layer, a TiN layer formed on the Ti layer, an AlCu layer formed on the TiN layer, and a TiN layer formed on the AlCu layer. The source electrode 212 and the drain electrode 214 may be in ohmic contact with the 2DEG immediately below the second nitride semiconductor layer 208 via the first opening 210A and the second opening 210B, respectively.

The nitride semiconductor device 200 may further include a first passivation layer 216 that covers the gate insulating layer 210, the source electrode 212, and the drain electrode 214, and a second passivation layer 218 formed on the first passivation layer 216. The first passivation layer 216 and the second passivation layer 218 partially cover each of the source electrode 212 and drain electrode 214.

The first passivation layer 216 has an opening 216A that exposes the gate insulating layer 210. The second passivation layer 218 formed on the first passivation layer 216 has an opening 218A having a width larger than the opening 216A. The opening 216A and the opening 218A may be located closer to the source electrode 212 than the drain electrode 214.

The first passivation layer 216 and the second passivation layer 218 may be made of SiN. Although not shown, an AIN layer may be formed as an etching stop layer between the first passivation layer 216 and the second passivation layer 218.

The nitride semiconductor device 200 further includes the gate electrode 220. The gate electrode 220 is formed on the second passivation layer 218 and fills the opening 216A and the opening 218A. The gate electrode 220 is in contact with the gate insulating layer 210 via the opening 216A and the opening 218A.

The source electrode 212 and the drain electrode 214 may be configured so that a source voltage and a drain voltage are respectively applied thereto. The semiconductor substrate 202 may be configured to be electrically connected to the source electrode 212 so that the source voltage is applied thereto. Therefore, the semiconductor substrate 202 may have the same potential as the source electrode 212. On the other hand, the semiconductor substrate 202 may have a different potential from the gate electrode 220 and the drain electrode 214.

### (Stacked Body of First Nitride Semiconductor Layer)

As described above, the first nitride semiconductor layer 206 includes one or more stacked bodies 206A. Each stacked body 206A includes a doped layer 222 which is a GaN layer doped with carbon, and a non-doped layer 224 which is a non-doped GaN layer and is formed on the doped layer 222. Each stacked body 206A is composed of a pair of the doped layer 222 and the non-doped layer 224. A carbon concentration in the doped layer 222 may be between 5×10¹⁷ cm⁻³ and 5×10¹⁹ cm⁻³.

In each stacked body 206A, the doped layer 222 may have the same thickness as the non-doped layer 224, or may have a different thickness from the non-doped layer 224. In addition, each stacked body 206A may have the same thickness as another stacked body 206A, or may have a different thickness from another stacked body 206A.

The first nitride semiconductor layer 206 has a structure in which the doped layers 222 and the non-doped layers 224 are alternately stacked. In the example of FIG. 5, the first nitride semiconductor layer 206 includes three stacked bodies 206A, that is, a first stacked body 206A1, a second stacked body 206A2, and a third stacked body 206A3. The first stacked body 206A1 includes a bottom surface 206B of the first nitride semiconductor layer 206. The third stacked body 206A3 includes a top surface 206C of the first nitride semiconductor layer 206. The first stacked body 206A1 is formed on the buffer layer 204. The second stacked body 206A2 is interposed between the first stacked body 206A1 and the third stacked body 206A3. The third stacked body 206A3 is formed on the second stacked body 206A2. The second nitride semiconductor layer 208 is formed on the third stacked body 206A3.

As shown in FIG. 5, the non-doped layer 224 has a bottom surface 224B that is in contact with the doped layer 222, and a top surface 224A opposite to the bottom surface 224B. The top surface 224A of the non-doped layer 224 of each stacked body 206A may be in contact with the doped layer 222 of another stacked body 206A or the second nitride semiconductor layer 208. In the example of FIG. 5, the top surface 224A of the non-doped layer 224 of the first stacked body 206A1 is in contact with the doped layer 222 of the second stacked body 206A2. The top surface 224A of the non-doped layer 224 of the second stacked body 206A2 is in contact with the doped layer 222 of the third stacked body 206A3. In addition, the top surface 224A of the non-doped layer 224 of the third stacked body 206A3 is in contact with the second nitride semiconductor layer 208.

Each stacked body 206A (the doped layer 222 and the non-doped layer 224) includes a plurality of dislocation lines similar to the dislocation lines 42 of the stacked body 16A (see FIG. 2). At least some of the plurality of dislocation lines are bent inside the stacked body 206A. At least some of the plurality of dislocation lines may extend continuously through both the doped layer 222 and the non-doped layer 224. The number of dislocation lines passing through the top surface 224A of the non-doped layer 224 is smaller than the number of dislocation lines passing through the bottom surface 224B thereof. This is because at least some of the plurality of dislocation lines are bent at an interface between the doped layer 222 and the non-doped layer 224 of each stacked body 206A. Since some of the dislocation lines bent at the interface (the bottom surface 224B of the non-doped layer 224) are coupled to each other in the non-doped layer 224, the number of dislocation lines passing through the top surface 224A of the non-doped layer 224 is smaller than the number of dislocation lines passing through the bottom surface 224B thereof. In the present modification, in a region below at least one of the gate electrode 220 or the drain electrode 214, the number of dislocation lines passing through the top surface 224A of the non-doped layer 224 is smaller than the number of dislocation lines passing through the bottom surface 224B thereof. In one example, the number of dislocation lines passing through the top surface 224A and the number of dislocation lines passing through the bottom surface 224B can be compared using values counted in a plurality of cross sections at different locations in the nitride semiconductor device 200.

A dislocation density of the non-doped layer 224 may be lower than a dislocation density of the doped layer 222. In addition, the dislocation density of the non-doped layer 224 may be lower in the stacked body 206A that is closer to the second nitride semiconductor layer 208 among the plurality of stacked bodies 206A (206A1, 206A2, and 206A3). That is, the dislocation density of the non-doped layer 224 of the third stacked body 206A3 may be lower than the dislocation density of the non-doped layer 224 of the second stacked body 206A2. In addition, the dislocation density of the non-doped layer 224 of the second stacked body 206A2 may be lower than the dislocation density of the non-doped layer 224 of the first stacked body 206A1.

With the nitride semiconductor device 200 according to the present modification, in the region below at least one of the gate electrode 220 or the drain electrode 214, the number of dislocation lines passing through the top surface 224A of the non-doped layer 224 is smaller than the number of dislocation lines passing through the bottom surface 224B thereof. As a result, current conduction between the bottom surface 224B and the top surface 224A of the non-doped layer 224 can be suppressed. Accordingly, a leakage current (for example, a gate leakage current, an off-leakage current, etc.) of the nitride semiconductor device 200 can be reduced.

### [Other Modifications]

The above-described embodiments and modifications can be modified and implemented as follows.

In each stacked body 16A, the doped layer 38 may have a smaller thickness than the non-doped layer 40. By making the thickness of the doped layer 38 relatively small, unevenness of the surface of the doped layer 38 can be made relatively large. As a result, bending of the dislocation lines 42 at the interface between the doped layer 38 and the non-doped layer 40 can be promoted.

In an active region of the nitride semiconductor device 10, the number of dislocation lines 42 passing through the top surface 40A of the non-doped layer 40 may be smaller than the number of dislocation lines 42 passing through the bottom surface 40B thereof. The active region of the nitride semiconductor device 10 may be a region that contributes to operations of the nitride semiconductor device 10 as a transistor. For example, the active region of the nitride semiconductor device 10 may be a region between the first opening 24A where the source electrode 26 is in contact with the second nitride semiconductor layer 18, and the second opening 24B where the drain electrode 28 is in contact with the second nitride semiconductor layer 18, in a plan view.

In the example shown in FIG. 1, the gate layer 20 may not include the source-side extension portion 32 and the drain-side extension portion 34. That is, the gate layer 20 may be formed to have a substantially uniform thickness.

One or more of the various examples described herein can be combined as long as they are not technically inconsistent. In the present disclosure, “at least one of A or B” should be understood as meaning “only A, only B, or both A and B.”

The term “on” as used in the present disclosure includes the meanings of “on” and “above” unless clearly stated otherwise in the context. Therefore, the expression “a first layer is formed on a second layer” is intended that in some embodiments, the first layer may be directly disposed on the second layer while being in contact with the second layer, but in other embodiments, the first layer may be disposed above the second layer without being in contact with the second layer. That is, the term “on” does not exclude a structure in which other layers are formed between the first and second layers. For example, the structure in which the second nitride semiconductor layer 18 is formed on the first nitride semiconductor layer 16 may include a structure in which an intermediate layer is located between the second nitride semiconductor layer 18 and the first nitride semiconductor layer 16 in order to form the 2DEG stably.

Further, the term “above” as used in the present disclosure includes the meaning of “on” and “above” unless clearly stated otherwise in the context. The terms indicating directions such as “vertical,” “horizontal,” “upward,” “downward,” “upper,” “lower,” “forward,” “backward,” “traversal,” “longitudinal,” “left,” “right,” “front,” “back,” and the like as used in the present disclosure depend on the particular orientation of a described and illustrated device. A variety of alternative orientations can be envisioned in the present disclosure, and thus these directional terms should not be interpreted narrowly.

For example, the Z-axis direction used in the present disclosure is not necessarily the vertical direction, and does not have to be exactly the same as the vertical direction. Therefore, in various structures (for example, the structure shown in FIG. 1) according to the present disclosure, “upper” and “lower” in the Z-axis direction described herein are not limited to “upper” and “lower” in the vertical direction, respectively. For example, the X-axis direction may be the vertical direction, or the Y-axis direction may be the vertical direction.

### [Supplementary Notes]

The technical ideas that can be recognized from the present disclosure are described below. In addition, for the purpose of aiding understanding and not for the purpose of limitation, components described in Supplementary Notes are labeled with the reference numerals of the corresponding components in the embodiments. The reference numerals are provided as examples to help understanding, and the components described in Supplementary Notes should not be limited to the components indicated by the reference numerals.

### (Supplementary Note 1)

A nitride semiconductor device including:
a first nitride semiconductor layer (16) made of a nitride semiconductor;
a second nitride semiconductor layer (18) formed on the first nitride semiconductor layer (16) and made of a nitride semiconductor having a bandgap larger than that of the first nitride semiconductor layer (16);
a gate electrode (22) located above the second nitride semiconductor layer (18); and
a source electrode (26) and a drain electrode (28) formed on the second nitride semiconductor layer (18),
wherein the first nitride semiconductor layer (16) includes one or more stacked bodies (16A), each of which includes a doped layer (38), which is a gallium nitride layer doped with carbon, and a non-doped layer (40) which is a non-doped gallium nitride layer formed on the doped layer (38),
wherein the non-doped layer (40) includes a plurality of dislocation lines (42), and has a bottom surface (40B) in contact with the doped layer (38) and a top surface (40A) opposite to the bottom surface (40B), and
wherein in a region below at least one of the gate electrode (22) or the drain electrode (28), the number of dislocation lines (42) passing through the top surface (40A) of the non-doped layer (40) is smaller than the number of dislocation lines (42) passing through the bottom surface (40B) of the non-doped layer (40).

### (Supplementary Note 2)

The nitride semiconductor device of Supplementary Note 1, wherein a dislocation density of the non-doped layer (40) is lower than a dislocation density of the doped layer (38).

### (Supplementary Note 3)

The nitride semiconductor device of Supplementary Note 1 or 2, wherein each stacked body (16A) includes a plurality of dislocation lines (42), and at least some of the plurality of dislocation lines (42) are bent inside the stacked body (16A).

### (Supplementary Note 4)

The nitride semiconductor device of Supplementary Note 3, wherein at least some of the plurality of dislocation lines (42) are bent at an interface between the doped layer (38) and the non-doped layer (40).

### (Supplementary Note 5)

The nitride semiconductor device of any one of Supplementary Notes 1 to 4, wherein the one or more stacked bodies (16A) include a first stacked body (16A1) and a second stacked body (16A2) formed on the first stacked body (16A1).

### (Supplementary Note 6)

The nitride semiconductor device of Supplementary Note 5, wherein a dislocation density of the non-doped layer (40) of the second stacked body (16A2) is lower than a dislocation density of the non-doped layer (40) of the first stacked body (16A1).

### (Supplementary Note 7)

The nitride semiconductor device of any one of Supplementary Notes 1 to 4, wherein the one or more stacked bodies (16A) are a plurality of stacked bodies (16A1, 16A2), and a dislocation density of the non-doped layer (40) is lower in the stacked body (16A2) that is closer to the second nitride semiconductor layer (18) among the plurality of stacked bodies (16A1, 16A2).

### (Supplementary Note 8)

The nitride semiconductor device of any one of Supplementary Notes 1 to 4, wherein the number of stacked bodies (16A) included in the first nitride semiconductor layer (16) is one, two, or three.

### (Supplementary Note 9)

The nitride semiconductor device of any one of Supplementary Notes 1 to 8, wherein a carbon concentration in the doped layer (38) is 5×10¹⁷ cm⁻³ or more and 5×10¹⁹ cm⁻³ or less.

### (Supplementary Note 10)

The nitride semiconductor device of any one of Supplementary Notes 1 to 9, further including: a gate layer (20) formed on the second nitride semiconductor layer (18) and made of a nitride semiconductor containing acceptor-type impurities, wherein the gate electrode (22) is formed on the gate layer (20).

### (Supplementary Note 11)

The nitride semiconductor device of Supplementary Note 10, wherein the gate layer (20) is made of gallium nitride containing at least one of Mg or Zn as impurities.

### (Supplementary Note 12)

The nitride semiconductor device of any one of Supplementary Notes 1 to 11, wherein the second nitride semiconductor layer (18) is made of AlₓGa₁₋ₓN, where x is 0<x<0.3.

### (Supplementary Note 13)

The nitride semiconductor device of any one of Supplementary Notes 1 to 12, further including:
a semiconductor substrate (12); and
a buffer layer (14) formed on the semiconductor substrate (12), wherein the first nitride semiconductor layer (16) is formed on the buffer layer (14).

### (Supplementary Note 14)

The nitride semiconductor device of Supplementary Note 13, wherein the semiconductor substrate (12) is electrically connected to the source electrode (26).

### (Supplementary Note 15)

The nitride semiconductor device of Supplementary Note 13 or 14, wherein the buffer layer (14) includes a plurality of AlGaN layers having different aluminum compositions from one another.

### (Supplementary Note 16)

A nitride semiconductor device including:
a first nitride semiconductor layer (16) made of a nitride semiconductor;
a second nitride semiconductor layer (18) formed on the first nitride semiconductor layer (16) and made of a nitride semiconductor having a bandgap larger than that of the first nitride semiconductor layer (16);
a gate electrode (22) located above the second nitride semiconductor layer (18); and
a source electrode (26) and a drain electrode (28) formed on the second nitride semiconductor layer (18),
wherein the first nitride semiconductor layer (16) includes a plurality of stacked bodies (16A), each of which includes a doped layer (38), which is a gallium nitride layer doped with carbon, and a non-doped layer (40) which is a non-doped gallium nitride layer formed on the doped layer (38).

The above description is merely an example. Those skilled in the art will appreciate that more possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A nitride semiconductor device comprising:
a first nitride semiconductor layer made of a nitride semiconductor;
a second nitride semiconductor layer formed on the first nitride semiconductor layer and made of a nitride semiconductor having a bandgap larger than that of the first nitride semiconductor layer;
a gate electrode located above the second nitride semiconductor layer; and
a source electrode and a drain electrode formed on the second nitride semiconductor layer,
wherein the first nitride semiconductor layer includes one or more stacked bodies, each of which includes a doped layer, which is a gallium nitride layer doped with carbon, and a non-doped layer which is a non-doped gallium nitride layer formed on the doped layer,
wherein the non-doped layer includes a plurality of dislocation lines, and has a bottom surface in contact with the doped layer and a top surface opposite to the bottom surface, and
wherein in a region below at least one of the gate electrode or the drain electrode, the number of dislocation lines passing through the top surface of the non-doped layer is smaller than the number of dislocation lines passing through the bottom surface of the non-doped layer.

2. The nitride semiconductor device of claim 1, wherein a dislocation density of the non-doped layer is lower than a dislocation density of the doped layer.

3. The nitride semiconductor device of claim 1, wherein each stacked body includes a plurality of dislocation lines, and at least some of the plurality of dislocation lines are bent inside the stacked body.

4. The nitride semiconductor device of claim 3, wherein at least some of the plurality of dislocation lines are bent at an interface between the doped layer and the non-doped layer.

5. The nitride semiconductor device of claim 1, wherein the one or more stacked bodies include a first stacked body and a second stacked body formed on the first stacked body.

6. The nitride semiconductor device of claim 5, wherein a dislocation density of the non-doped layer of the second stacked body is lower than a dislocation density of the non-doped layer of the first stacked body.

7. The nitride semiconductor device of claim 1, wherein the one or more stacked bodies are a plurality of stacked bodies, and a dislocation density of the non-doped layer is lower in the stacked body that is closer to the second nitride semiconductor layer among the plurality of stacked bodies.

8. The nitride semiconductor device of claim 1, wherein the number of stacked bodies included in the first nitride semiconductor layer is one, two, or three.

9. The nitride semiconductor device of claim 1, wherein a carbon concentration in the doped layer is 5×10¹⁷ cm⁻³ or more and 5×10¹⁹ cm⁻³ or less.

10. The nitride semiconductor device of claim 1, further comprising a gate layer formed on the second nitride semiconductor layer and made of a nitride semiconductor containing acceptor-type impurities,
wherein the gate electrode is formed on the gate layer.

11. The nitride semiconductor device of claim 10, wherein the gate layer is made of gallium nitride containing at least one of Mg or Zn as impurities.

12. The nitride semiconductor device of claim 1, wherein the second nitride semiconductor layer is made of AlₓGa₁₋ₓN, where x is 0<x<0.3.

13. The nitride semiconductor device of claim 1, further comprising:
a semiconductor substrate; and
a buffer layer formed on the semiconductor substrate,
wherein the first nitride semiconductor layer is formed on the buffer layer.

14. The nitride semiconductor device of claim 13, wherein the semiconductor substrate is electrically connected to the source electrode.

15. The nitride semiconductor device of claim 13, wherein the buffer layer includes a plurality of AlGaN layers having different aluminum compositions from one another.
